(19) United States
(12) Patent Application Publication
(10) Pub. No.: US 2006/0250771 A1
(43) Pub. Date: Nov. 9, 2006

(54) Illuminating apparatus

(75) Inventors: Helmut Heine, Diessen (DE); Oliver Heine, Herrsching (DE); Sebastian Duy, Otterfing (DE); Hartmut Schloesser, Poecking (DE); Dirk Schade, Penzberg (DE)

Correspondence Address: ROTHWELL, FIGG, ERNST & MANBECK, P.C., 1425 K STREET, N.W., SUITE 800, WASHINGTON, DC, 20005, US

(73) Assignee: Heine Optotechnik GmbH & Co., KG, Herrsching (DE)

(21) Appl. No.: 11/357,140

(22) Filed: Feb. 21, 2006

(30) Foreign Application Priority Data
May 6, 2005 (DE) 20 2005 007 211.7

(51) Int. Cl. H05K 7/20

(52) U.S. Cl. 361/695

(57) ABSTRACT

An illuminating apparatus for handheld or headworn instruments comprises a luminous means (50), a heat sink (42) for dissipating heat produced by the luminous means (50), and a ventilation device (57), fitted on the heat sink (42), for feeding cooling air to the heat sink (42). A damping device (60) for damping the oscillations generated by the ventilation device (57) is provided between the heat sink (42) and the ventilation device (57).

### BACKGROUND OF THE INVENTION

1. Field of the Invention

The invention relates to an illuminating apparatus for handheld or headworn a luminous means, comprising a heat sink for dissipating heat produced by the luminous means, and a ventilation device, mounted on the heat sink, for feeding cooling air to the heat sink.

2. Description of the Background Art

Such illuminating apparatuses are used inter alia with headlamps, ophthalmoscopes and luminous means for binocular magnifiers. Arranged in these illuminating apparatuses as luminous means is, for example, a light-emitting diode with a power of 3 W, or a halogen lamp that generates through power loss a large quantity of heat that must be dissipated in order to prevent damage to the luminous means and the electronics associated therewith, as well as to prevent excessive heating of the housing. It is known for the purpose of dissipating the heat to use relatively large heat sinks that are heavy and voluminous and this is disagreeable, in particular, when using headworn instruments and lighting devices.

In order to eliminate this disadvantage, an illuminating apparatus has been developed as shown in FIG. 1. The known illuminating apparatus 10 comprises a heat sink 12 made from aluminum and having a base 24 at whose front side a row of cooling webs 14 extend upwards, and at whose two lateral regions a row of cooling webs 16, 18, 20, 22 respectively extend upwards. Mounted at the underside of the base 24 is an LED 26 in whose illuminating path a positive lens 28 is arranged. A cuboid housing 29 of a fan 30 is mounted on the cooling webs 16, 18, 20, 22. Provided in the corner regions of the fan 30 are vertically penetrating through bores 31 through which pass fastening screws 32 by means of which the housing 29 is fastened at the upper end faces of the front cooling webs 16 and of the rear cooling webs 22. The fan 30 is used to actively ventilate the heat sink 12 in order to backup the dissipation of heat. This renders it possible to use a very compact and thus light heat sink 12, it being possible at the same time for the resulting power loss of the light source 26 to be dissipated very effectively. However, it has been shown in practice that the fan 30 produces vibrations that the user finds disturbing when working.

### SUMMARY OF THE INVENTION

It is the object of the invention to provide with the aid of means of simple design a compact and light illuminating apparatus that is agreeable to wear for the user.

This object is achieved according to the invention by means of an illuminating apparatus for handheld or headworn instruments, comprising a luminous means, a heat sink for dissipating heat produced by said luminous means, and a ventilation device, mounted on said heat sink, for feeding cooling air to said heat sink, wherein a damping device for damping oscillations generated by said ventilation device is provided between said heat sink and said ventilation device.

In the case of the illuminating apparatus according to the invention, there is provided between the heat sink and the ventilation device a damping device that damps the oscillations and vibrations produced by the ventilation device such that they are no longer perceptible to the user and therefore have no disturbing effect.

The ventilation device is conveniently formed by a fan with an impeller.

In a preferred embodiment of the illuminating apparatus according to the invention, the damping device is formed by a number of columnar damping elements that are fastened with one end on the housing of the ventilation device, and with the other end on the base of the heat sink. This enables the housing to oscillate freely without the oscillation being transmitted to the heat sink.

A thermoplastic with a Shore hardness of less than 70 A is the preferred material for the damping elements.

### BRIEF DESCRIPTION OF THE DRAWINGS

An exemplary embodiment of the invention is explained in more detail below with the aid of drawings, in which:

FIG. 1 shows a known illuminating apparatus, and

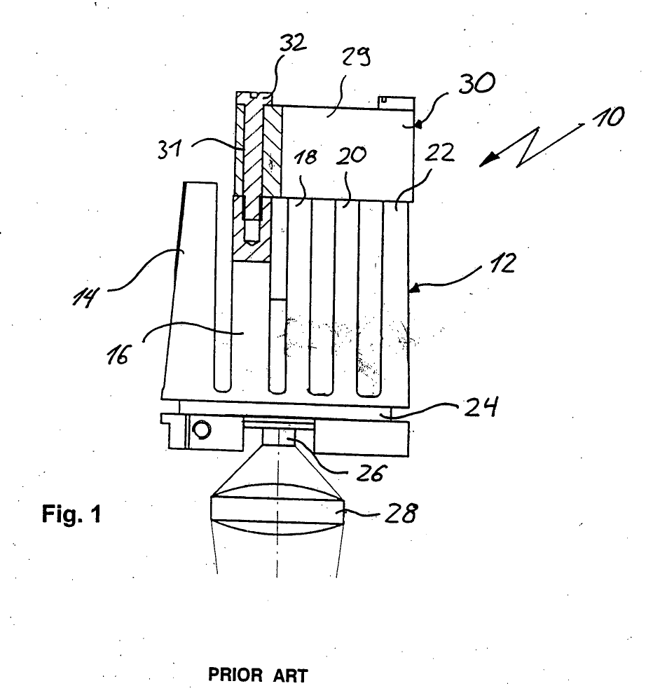

FIG. 2 shows an illuminating apparatus of the invention.

### DETAILED DESCRIPTION OF THE INVENTION

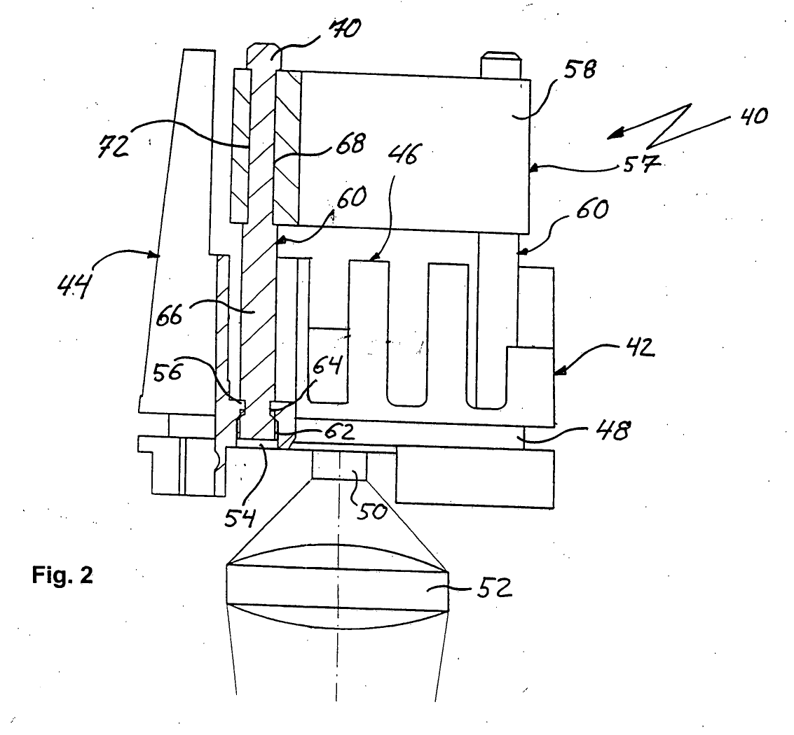

The illuminating apparatus 40 according to the invention comprises a heat sink 42 made from aluminum that is bounded below by a base 48. Extending upward from the base 48 at the front, that is to say on the left-hand side in FIG. 2, is a row of long cooling webs 44 of which only one is to be seen because of the side view. On each of both sides of the heat sink 42 a respective row of lateral cooling webs 46 is arranged with spacing to each other, the height of the lateral cooling webs corresponding approximately to half the height of the front cooling webs 44. An LED 50 is mounted centrally on the underside of the base 48. A positive lens 52 is arranged in the illuminating path below the LED 50.

For the purpose of active ventilation of the heat sink 42, a fan 57 with an impeller is arranged above the end faces of the cooling webs 46 and essentially comprises a cuboid housing 58, the housing 58 being situated deeper than the upper end face of the cooling webs 44.

The housing 58 is mounted in a freely oscillating fashion on the base 48 with the aid of four columnar damping elements 60 made from elastic polymer and arranged in the corner regions of the housing 58. At the bottom, the damping elements 60 are each guided through a throughbore 54 in the base 48, there being formed at the upper end of the throughbore 54 an inwardly extending collar 56 that engages in a constriction 64 in the damping element 60. Adjoining the constriction 64 is a column part 66 of greater diameter that extends up to the underside of the housing 58. Following the column part 66 is a further constriction 68 of the damping element 60, whose length corresponds to the height of the housing 58 and which bears with its outer circumference against the inner circumference of a vertical throughbore 72 through the housing 58. Formed adjacent to the constriction 68 is a head end 70 of greater diameter that bears with its underside against the top side of the housing 58. The four damping elements 60 form a freely oscillating bearing of the fan 57 such that no vibrations of the fan 57 are transmitted to the heat sink 42.

1. An illuminating apparatus for handheld or headworn instruments, comprising a luminous means, a heat sink for dissipating heat produced by said luminous means, and a ventilation device, mounted on said heat sink, for feeding cooling air to said heat sink, wherein a damping device for damping oscillations generated by said ventilation device is provided between said heat sink and said ventilation device.

2. The illuminating apparatus as claimed in claim 1, wherein said ventilation device is formed by a fan having an impeller.

3. The illuminating apparatus as claimed in claim 1, wherein said ventilation device comprises a housing, and said damping device is formed by a number of columnar damping elements that are fastened with one end thereof on said housing and with another end thereof on said base of said heat sink.

4. The illuminating apparatus as claimed in claim 1, wherein said damping elements are formed of a thermoplastic material with a Shore hardness of less than 70 A.
